(19) United States
(12) Patent Application Publication
(10) Pub. No.: US 2026/0173566 A1
(43) Pub. Date: Jun. 18, 2026

(54) SEMICONDUCTOR DEVICE

(71) Applicant: Samsung Electronics Co., Ltd., Suwon-si (KR)

(72) Inventors: Koji Hamaguchi, Yokohama (JP); Tsuyoshi Ogawa, Yokohama (JP)

(21) Appl. No.: 19/317,042

(22) Filed: Sep. 2, 2025

(30) Foreign Application Priority Data
Dec. 12, 2024 (JP) 2024-217187
Feb. 27, 2025 (KR) 10-2025-0026020

(51) Int. Cl. H10F 39/00

(52) U.S. Cl. CPC H10F 39/811; H10F 39/804

(57) ABSTRACT

A semiconductor device includes a substrate, a semiconductor chip mounted on the substrate and having a first surface and a second surface opposite to the first surface, a plurality of connection terminals configured to electrically connect the semiconductor chip to the substrate, and a resin layer having a thickness of 100 μm or more and provided between the second surface of the semiconductor chip and the plurality of connection terminals, wherein the resin layer includes one or more supports protruding in a thickness direction of the resin layer, one of the plurality of connection terminals is disposed on one of the one or more supports, and the support has a thickness that is 33% or more of the thickness of the resin layer.

### CROSS-REFERENCE TO RELATED APPLICATIONS

This application claims the benefit of Japanese Patent Application No. 2024-217187, filed on Dec. 12, 2024, in the Japanese Patent Office and Korean Patent Application No. 10-2025-0026020, filed on Feb. 27, 2025, in the Korean Intellectual Property Office, the disclosures of which are incorporated herein in their entireties by reference.

### TECHNICAL FIELD

The present disclosure relates to a semiconductor device.

### BACKGROUND

Recently, in order to reduce the size of semiconductor chips and increase the degree of integration thereof, flip chip mounting, in which semiconductor devices are provided as a chip-scale package (CSP), has been actively employed.

A CSP has a small size, similar to that of a semiconductor chip, which improves the productivity in a wafer-level process. However, the CSP lacks solder connection reliability during package mounting. The reason for the low reliability of solder connection during the package mounting of CSP is due to the significant difference between the coefficient of linear expansion of silicon (about 2.6 ppm/° C. to about 4.2 ppm/° C.), which constitutes a chip body in a semiconductor chip that serves as a base body of CSP, and the coefficient of linear expansion of a mounting substrate (about 15 ppm/° C. to about 20 ppm/° C.), such as a motherboard on which the CSP is mounted. Accordingly, stress imposed on connection terminals and surrounding regions thereof increases due to the difference in thermal expansion during temperature changes such as temperature cycles.

Patent document 1 (JP 2005-094040 A) discloses a semiconductor device, wherein a low-elasticity, thick stress relief layer stacked on an insulating film on a semiconductor chip is provided between the semiconductor chip, wires, and lands to improve the reliability of external terminals (connectors) against deformation caused by the difference in thermal expansion between the semiconductor chip and a printed circuit board.

In the semiconductor device of Patent document 1 (JP 2005-094040 A), the stress relief layer is formed as a single layer having a substantially uniform thickness, and all connectors are disposed on the stress relief layer. Therefore, when deformation occurs in the semiconductor device in Patent document 1, the stress relief layer deforms entirely to absorb the stress, and thus, the stress relief effect is limited. Therefore, the semiconductor device in Patent document 1 needs improvement in terms of the reliability of solder connection.

### SUMMARY

The present disclosure provides a semiconductor device capable of improving reliability of solder connection according to changes in temperature during package mounting.

According to an aspect of the present disclosure, there is provided a semiconductor device including a substrate, a semiconductor chip mounted on the substrate and having a first surface and a second surface opposite to the first surface, a plurality of connection terminals configured to electrically connect the semiconductor chip to the substrate, and a resin layer having a thickness of 100 μm or more and provided between the second surface of the semiconductor chip and the plurality of connection terminals, wherein the resin layer includes one or more supports protruding in a thickness direction of the resin layer, one of the plurality of connection terminals is disposed on one of the one or more supports, and the support has a thickness that is 33% or more of the thickness of the resin layer.

According to another aspect of the present disclosure, there is provided a semiconductor device including a substrate, a semiconductor chip mounted on the substrate and having a first surface and a second surface opposite to the first surface, electrodes disposed on the first surface of the semiconductor chip, a plurality of connection terminals provided on the second surface of the semiconductor chip and configured to electrically connect the semiconductor chip to the substrate, a resin layer between the second surface of the semiconductor chip and the plurality of connection terminals, an insulating layer between the second surface of the semiconductor chip and the resin layer, wires disposed on the resin layer, wherein the plurality of connection terminals are electrically connected to the electrodes via the wires, and a protective layer covering the insulating layer and the wires, wherein the resin layer includes supports protruding in a thickness direction of the resin layer, the plurality of connection terminals include first connection terminals, the first connection terminals are individually disposed on the supports, the resin layer has a thickness of 100 μm or more, and each of the supports has a thickness that is 33% or more of the thickness of the resin layer.

### BRIEF DESCRIPTION OF THE DRAWINGS

Embodiments will be more clearly understood from the following detailed description taken in conjunction with the accompanying drawings in which:

FIG. 1 is a schematic cross-sectional view showing a state in which a semiconductor device according to some embodiments is mounted on a substrate;

FIG. 2 is a schematic cross-sectional view of a semiconductor device according to some embodiments;

FIG. 3A is a schematic cross-sectional view of a semiconductor device and illustrates some embodiments of a resin layer;

FIG. 3B is a schematic cross-sectional view of a semiconductor device and illustrates some embodiments of a resin layer;

FIG. 4A is a partial schematic cross-sectional view of a semiconductor device and illustrates a state before a resin layer is deformed due to a temperature change;

FIG. 4B is a partial schematic cross-sectional view of a semiconductor device and illustrates a state after a resin layer is deformed due to a temperature change;

FIG. 5A is a plan view of a semiconductor device having a resin layer in Example 1;

FIG. 5B is a schematic cross-sectional view of the semiconductor device taken along line A-A′ of FIG. 5A;

FIG. 6A is a plan view of a semiconductor device having a resin layer in Example 2;

FIG. 6B is a schematic cross-sectional view of the semiconductor device taken along line B-B′ of FIG. 6A;

FIG. 7A is a plan view of a semiconductor device having a resin layer in Example 3;

FIG. 7B is a schematic cross-sectional view of the semiconductor device taken along line C-C′ of FIG. 7A;

FIG. 8A is a plan view of a semiconductor device having a resin layer in Example 4;

FIG. 8B is a schematic cross-sectional view of the semiconductor device taken along line D-D′ of FIG. 8A;

FIG. 9A is a plan view of a semiconductor device having a resin layer in Example 5;

FIG. 9B is a schematic cross-sectional view of the semiconductor device taken along line E1-E1′ of FIG. 9A;

FIG. 9C is a schematic cross-sectional view of the semiconductor device taken along line E2-E2′ of FIG. 9A;

FIG. 10A is a plan view of a semiconductor device having a resin layer in Example 6;

FIG. 10B is a schematic cross-sectional view of the semiconductor device taken along line F1-F1′ of FIG. 10A;

FIG. 10C is a schematic cross-sectional view of the semiconductor device taken along line F2-F2′ of FIG. 10A;

FIG. 11A is a plan view schematically showing a wire in a semiconductor device in layout example 1, according to some embodiments;

FIG. 11B is a schematic cross-sectional view of the semiconductor device taken along line A1-B1-D1-E3 of FIG. 11A;

FIG. 11C is a schematic cross-sectional view of the semiconductor device taken along line A1-B1-C1 of FIG. 11A;

FIG. 12A is a plan view schematically showing a wire in a semiconductor device in layout example 2, according to some embodiments;

FIG. 12B is a schematic cross-sectional view of the semiconductor device taken along line A2-B2-C2 of FIG. 12A;

FIG. 13A is a plan view schematically showing a wire in a semiconductor device in layout example 3;

FIG. 13B is a schematic cross-sectional view of the semiconductor device taken along line A3-B3-C3 of FIG. 13A;

FIG. 14 is a table showing model conditions based on a simulation, according to some embodiments;

FIG. 15 is a table showing material properties based on a simulation, according to some embodiments;

FIG. 16A is a plan view showing a ⅛ model of a semiconductor device used in a simulation;

FIG. 16B is a side view of the ⅛ model of the semiconductor device in FIG. 16A;

FIG. 17A is a table showing simulation results according to some embodiments;

FIG. 17B is a table showing simulation results according to some embodiments;

FIG. 17C is a table showing simulation results according to some embodiments;

FIG. 17D is a table showing simulation results according to some embodiments;

FIG. 18A is a plan view schematically showing a structure of a semiconductor device of samples 1 to 8, according to some embodiments;

FIG. 18B is a schematic cross-sectional view of the semiconductor device taken along line G-G′ of FIG. 18A;

FIG. 19A is a plan view schematically showing a structure of a semiconductor device of samples 9 to 20, according to some embodiments;

FIG. 19B is a schematic cross-sectional view of the semiconductor device taken along line H-H′ of FIG. 19A;

FIG. 20A is a plan view schematically showing a structure of a semiconductor device of samples 21 to 26, according to some embodiments;

FIG. 20B is a schematic cross-sectional view of the semiconductor device taken along line I-I′ of FIG. 20A;

FIG. 21A is a plan view schematically showing a structure of a semiconductor device of samples 27 and 28, according to some embodiments;

FIG. 21B is a schematic cross-sectional view of the semiconductor device taken along line J-J′ of FIG. 21A;

FIG. 22A is a plan view schematically showing a structure of a resin layer of a semiconductor device of sample 29;

FIG. 22B is a schematic cross-sectional view of the semiconductor device taken along line K-K′ of FIG. 22A;

FIG. 23A is a plan view schematically showing a structure of a resin layer of a semiconductor device of sample 30; and

FIG. 23B is a schematic cross-sectional view of the semiconductor device taken along line L-L′ of FIG. 23A.

### DETAILED DESCRIPTION OF THE EMBODIMENTS

Hereinafter, embodiments are described in detail with reference to the accompanying drawings. In the following drawings, the same reference numerals refer to the same components, and the size of each of components in the drawings may be exaggerated for clarity and convenience of illustration. Also, embodiments described below are only examples, and thus, various changes may be made from the embodiments.

Hereinafter, when an element is referred to as being “above” or “on” another element, not only may the element be directly above and in contact with another element, but also the element may be above but not in contact with another element. Similarly, when an element is referred to as being “below” or “on” another element, not only may the element be directly below and in contact with another element, but also the element may be below but not in contact with another element.

The singular forms include the plural forms as well, unless the context clearly indicates otherwise. In addition, when it is described that a part “includes,” “is provided with,” or “has” a certain component, this indicates that the part may further include other components, rather than excluding other components, unless specifically stated to the contrary.

Unless the order of operations constituting a method is explicitly stated or otherwise indicated, the operations are to be performed in any suitable order. The method is not necessarily limited to the order of operations described above. All examples or illustrative terms are only used to explain the technical idea, and the scope of the present disclosure is not limited by these examples or illustrative terms unless otherwise limited by the claims.

Also, the ordinal numbers, such as “first” and “second,” given in the following description are used for convenience of description and are not intended to indicate any particular order, unless otherwise specified.

A semiconductor device 1 shown in each embodiment may have a package structure. The package structure may include a wafer-level chip scale package (CSP) in which a semiconductor chip 20 is provided as a solid-state image capturing element (a complementary metal-oxide-semiconductor (CMOS) image sensor). Also, the package structure of the semiconductor device 1 may have a fan-out package.

The semiconductor device 1 according to some embodiments is described below with reference to drawings.

Here, for convenience of description, an XYZ orthogonal coordinate system is set for the semiconductor device 1. In a certain plane, a direction parallel to an X-axis is defined as an X-axis direction. In a certain plane, a direction parallel to a Y-axis perpendicular to the X-axis is defined as a Y-axis direction. A direction parallel to a Z-axis, which is perpendicular to both the X-axis and the Y-axis, is defined as a Z-axis direction. In some embodiments, the certain plane is parallel to a horizontal plane in an XY plane, and the Z-axis represents a vertical direction perpendicular to the certain plane and is defined as an axis in a thickness direction (e.g., a direction perpendicular to a major surface of the semiconductor device 1) of the semiconductor device 1.

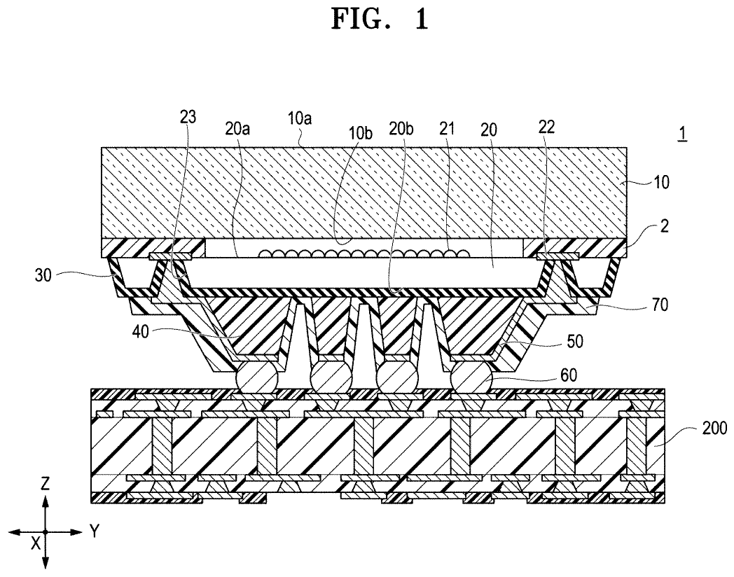

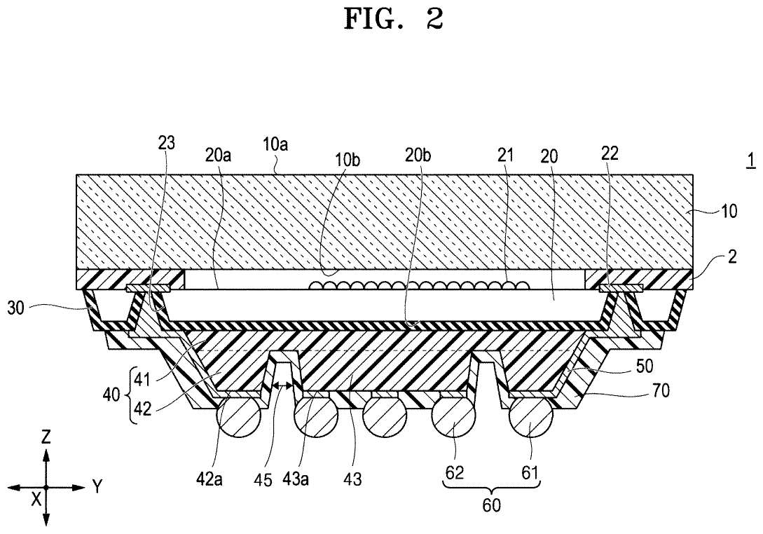

As illustrated in FIGS. 1 and 2, the semiconductor device 1 includes a transparent substrate 10, the semiconductor chip 20, an insulating layer 30, a resin layer 40, a wire 50, a connection terminal 60, and a protective layer 70. The semiconductor device 1 may be mounted on a substrate 200 via the connection terminal 60 as shown in FIG. 1.

The transparent substrate 10 includes a light-transmissive inorganic or organic material. The transparent substrate 10 may include glass, germanium, silicon, and/or acrylic.

The transparent substrate 10 has a first surface 10a, which is a light incident surface, and a second surface 10b, which is opposite to the first surface 10a, as shown in FIG. 2. The transparent substrate 10 is bonded to the semiconductor chip 20 by a bonding portion 2 in a state in which the second surface 10b of the transparent substrate 10 faces a first surface 20a of the semiconductor chip 20. The bonding portion 2 may include a sealing material (a dam material). In FIG. 1, the first surface 10a of the transparent substrate 10 represents the upper surface of the transparent substrate 10, and the second surface 10b of the transparent substrate 10 represents the lower surface of the transparent substrate 10.

The semiconductor chip 20 has a chip body. The chip body may include silicon or the like. The semiconductor chip 20 has the first surface 20a, which is a light incident surface, and a second surface 20b, which is opposite to the first surface 20a. An integrated circuit (IC) pattern is formed on the first surface 20a. In FIG. 2, the first surface 20a of the semiconductor chip 20 represents the upper surface of the chip body, and the second surface 20b of the semiconductor chip 20 represents the lower surface of the chip body.

The semiconductor chip 20 may have a light-receiving region. A plurality of pixels may be arranged in rows and columns on the light-receiving region of the semiconductor chip 20. The plurality of pixels may convert incident light into electrical signals. The semiconductor chip 20 may be provided as a CMOS image sensor equipped with an on-chip lens (a microlens) 21 and at least one of a color filter, a photodiode, and a pixel circuit (not shown). The on-chip lens (the microlens) 21 may be spaced apart laterally from an electrode 22.

The electrode 22 may be formed on the first surface 20a of the semiconductor chip 20. A through-via 23 may be formed from the second surface 20b of the semiconductor chip 20 to the electrode 22 to establish electrical connection with the electrode 22. The through-via 23 may be formed by a process, such as deep reactive ion etching (DRIE).

An insulating layer 30 is formed on the second surface 20b and side surfaces of the semiconductor chip 20 and on side surfaces of the through-via 23. The insulating layer 30 may be formed by thin film formation processes, such as deposition, sputtering, and chemical vapor deposition (CVD). The insulating layer 30 may be formed by removing a portion of a preliminary insulating layer which is formed on a facing surface of the electrode 22 corresponding to the bottom of the through-via 23.

The resin layer 40 may be formed on at least a portion of the insulating layer 30. The connection terminal 60 may be disposed on at least a portion of the insulating layer 30 and on the resin layer 40.

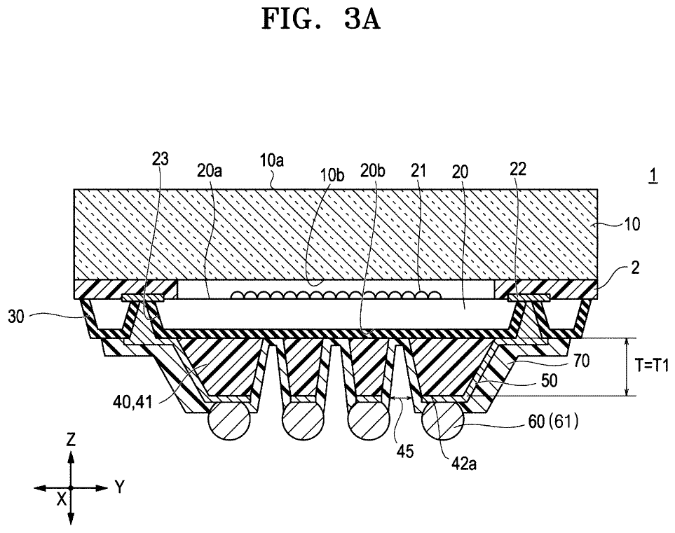

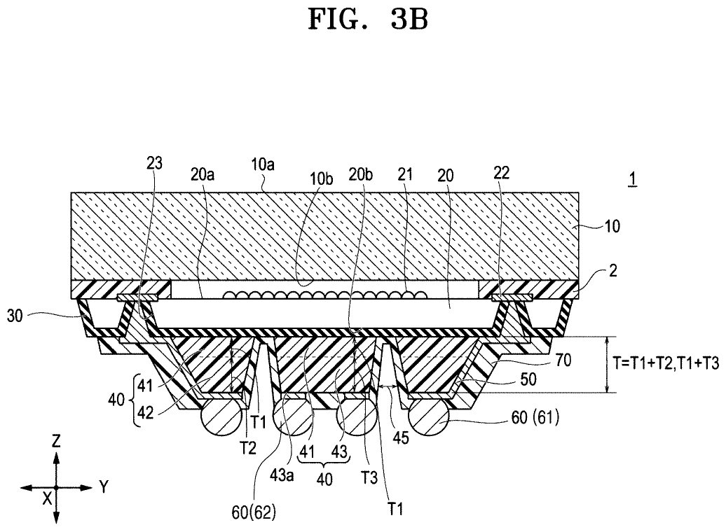

As illustrated in FIG. 2, the resin layer 40 may include a support 42. The resin layer 40 may include at least one more of the support 42 and a ridge 43. For example, the resin layer 40 may include a base 41, a support 42, and a ridge 43. Also, regions in the resin layer 40 are separated from each other by boundaries with dashed lines for convenience of illustration in FIGS. 2, 3A, and 3B, but in an actual structure, these regions may have the same material and be integrally formed.

The base 41 is located in the resin layer 40 on the side of the semiconductor chip 20. For example, the base 41 may be disposed on the second surface 20b of the semiconductor chip 20. The base 41 may be located between the semiconductor chip 20 and the support 42. The base 41 may extend on the second surface 20b of the semiconductor chip 20 in a planar direction perpendicular to the thickness direction (e.g., a direction perpendicular to a major surface of the resin layer 40) of the resin layer 40. For example, the base 41 may extend on the second surface 20b of the semiconductor chip 20 in the planar direction parallel to the second surface 20b of the semiconductor chip 20. The support 42 or the ridge 43 may be formed on the base 41 on the side of the connection terminal 60. Also, the thickness of the base 41 may be less than the thickness of the support 42. For example, the thickness of the base 41 may be 0. In this case, the base 41 may be omitted, and the support 42 or the ridge 43 may be directly disposed on the insulating layer 30.

The support 42 may have a terminal surface 42a and may be formed in a protruding shape, for example, a conical shape, a portion of a conical shape, a quadrangular cone, a portion of a quadrangular cone, or a cylindrical shape. As used herein, the terminal surface may represent the surface on which a terminal is formed. The support 42 is formed at a location corresponding to the formation position of the connection terminal 60. The connection terminal 60 may be disposed on the terminal surface 42a of the support 42. For example, supports 42 and connection terminals 60 may be in a one-to-one relationship. For example, one connection terminal 60 may be disposed on one support 42. The support 42 may have a thickness that is 33% or more of the thickness of the resin layer 40. Accordingly, the support 42 may effectively absorb deformation due to temperature changes, thereby improving the reliability of the solder connection of the connection terminal 60. The support 42 may represent any one of a plurality of supports 42.

According to embodiments, the connection terminal 60 may include a plurality of first connection terminals 61. The plurality of first connection terminals 61 may be individually disposed on the plurality of supports 42.

The ridge 43 may be provided adjacent to the support 42. The ridge 43 may be spaced apart from the support 42 in a lateral direction (the X-axis direction or the Y-axis direction). When the resin layer 40 includes the base 41, the base 41 may be located between the semiconductor chip 20 and the ridge 43. The ridge 43 may protrude from the base 41. For example, the ridge 43 may protrude from the base 41 in the direction opposite to the Z-axis direction. A plurality of connection terminals 60 may be disposed on the ridge 43. Specifically, the connection terminal 60 may further include a plurality of second connection terminals 62. The plurality of second connection terminals 62 may be disposed on the ridge 43. The ridge 43 may have a terminal surface 43a. The plurality of second connection terminals 62 may be disposed on the terminal surface 43a of the ridge 43. The number and positions of the plurality of second connection terminals 62 disposed on the ridge 43 may be arbitrarily set according to the specifications of the semiconductor device 1.

A gap 45 may be provided between one support 42 and another support 42 adjacent thereto or between one support 42 and the ridge 43 adjacent thereto. For example, the gap 45 may correspond to a gap region and include an empty space occupied by air.

As shown in FIG. 3A, when the base 41 is not provided below the support 42 in the resin layer 40, a thickness T2 of the support 42 corresponds to a thickness T of the resin layer 40. Therefore, the height of the resin layer 40 is equal to the height of the support 42 shown in FIG. 3A.

As shown in FIG. 3B, when the resin layer 40 includes the base 41, the support 42, and the ridge 43, the support 42 and the ridge 43 may be disposed on the base 41. As shown in FIG. 3B, the thickness T of the resin layer 40 may be substantially equal to the sum of a thickness T1 of the base 41 and a thickness T2 of the support 42. The thickness T of the resin layer 40 may be substantially equal to the sum of the thickness T1 of the base 41 and a thickness T3 of the ridge 43. The thickness of the resin layer 40 may be measured by using a micrometer after the formation of the resin layer 40 in a manufacturing process or by using a measuring function of a microscope after cutting a package when the package is completely manufactured. Also, the resin layer 40 is formed by appropriately combining the base 41, the support 42, and the ridge 43 as shown in FIGS. 3A and 3B, and the thickness T of the resin layer 40 represents the total thickness of the resin layer 40.

The resin layer 40 may include at least one of a photosensitive material and an insulating resin. The photosensitive material may be applied to various other semiconductor packages, such as solder resist. The insulating resin may include epoxy resin. When the resin layer 40 includes the photosensitive material, the resin layer 40 and the semiconductor device 1 including same may be easily formed. In addition, the resin layer 40 may further include a non-conductive filler. The non-conductive filler may be provided in the photosensitive material or insulating resin. The non-conductive filler may include spherical silica. Also, the non-conductive filler may have a flat shape and include an inorganic filler. The reliability of solder connection of the semiconductor device 1 may be improved by adjusting the non-conductive filler content of the resin layer 40. As the non-conductive filler content of the resin layer 40 is adjusted, the coefficient of linear expansion and elastic modulus of the resin layer 40 itself may be adjusted. Therefore, the filler content of the resin layer 40 may be adjusted so that the reliability of solder connection is improved. Accordingly, the semiconductor device 1 may form a package having the excellent reliability of solder connection.

When the resin layer 40 is formed by using a photosensitive resin material, the support 42 may be formed by shaping the photosensitive resin material into a desired shape and then exposing the shaped material to light. When the resin layer 40 is formed by using the insulating resin, such as epoxy resin, the support 42 may be formed by shaping the resin layer 40 to the required thickness and then cutting away unnecessary regions. Also, the support 42 may be formed simultaneously with the resin layer 40 when the resin layer 40 is formed by using a die or the like.

When the resin layer 40 is formed by using the insulating resin, the insulating resin may have the elastic modulus of about 10 GPa to about 20 GPa. For example, the insulating resin may include a semiconductor sealing material, and thus, the elastic modulus described above may be satisfied. When the resin layer 40 is excessively thin, the effect of absorbing deformation may deteriorate. When the resin layer 40 is excessively thick, a wafer may not enter a stocker or a wafer may be bent. Therefore, the thickness T of the resin layer 40 is preferably in a range of about 100 μm to about 800 μm (depending on conditions of the stocker). Also, since the thickness T of the resin layer 40 is 800 μm or less, bending of the resin layer 40 may be effectively suppressed. The elastic modulus may represent a storage modulus that may be measured, for example, by dynamic viscoelastic measurements. Also, the elastic modulus may be measured by bending tests using a universal testing machine. Also, the elastic modulus may represent a longitudinal elastic modulus (a Young's modulus) measured by a tensile test.

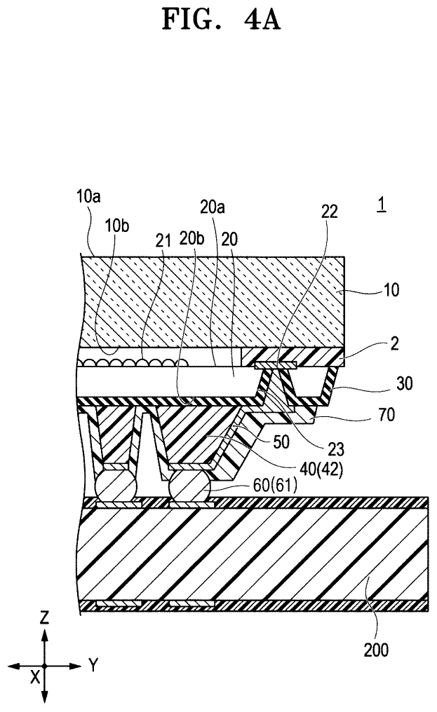

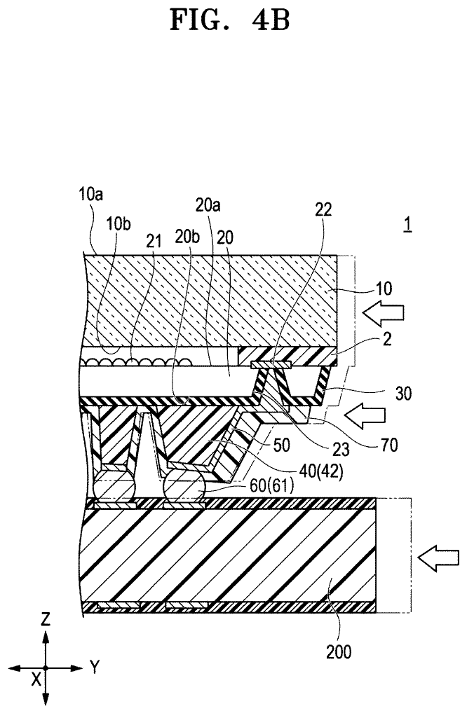

FIG. 4A shows the semiconductor device 1 before heat shrinkage. FIG. 4B shows the semiconductor device 1 after heat shrinkage. The dash-double dotted line in FIG. 4B represents the outline of the semiconductor device 1 before heat shrinkage. As shown in FIG. 4B, when the semiconductor device 1 is entirely contracted by heat shrinkage, stress is applied to the connection terminals 60. The stress is caused by the difference in thermal expansion, and may occur because the amount of contraction of the substrate 200 is greater than the amount of contraction of the transparent substrate 10 or the semiconductor chip 20. However, according to embodiments, the supports 42 formed individually and independently may be tilted and deformed individually to effectively relieve the stress. That is, the semiconductor device 1 according to embodiments may effectively absorb stress due to thermal shrinkage and thus maintain the connection state of the connection terminals 60.

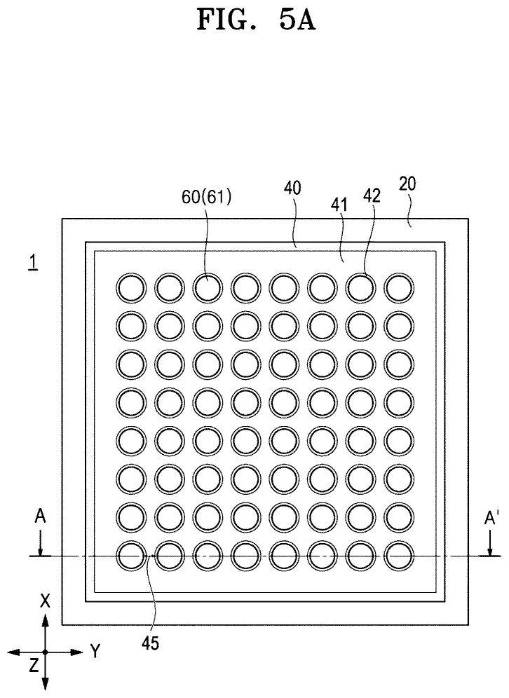

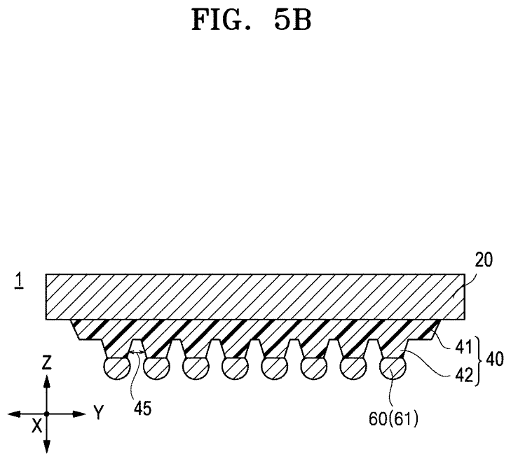

Next, some embodiments of the resin layer 40 are illustrated. In Examples 1 to 6, the resin layer 40 includes the base 41, but may not include the base 41. In addition, semiconductor devices 1 shown in FIGS. 5A to 10B are simplified for ease of illustration by schematically showing only semiconductor chips 20, resin layers 40, and connection terminals 60. The resin layer 40 is not limited to the shapes shown in Examples 1 to 6 described below.

### Example 1

FIG. 5A is a plan view of the semiconductor device 1 having the resin layer 40 in Example 1. FIG. 5B is a schematic cross-sectional view of the semiconductor device 1 taken along line A-A′ of FIG. 5A.

Referring to FIGS. 5A and 5B, the supports 42 may be formed individually so as to correspond to the connection terminals 60 in Example 1. The connection terminals 60 may represent the first connection terminals 61. According to Example 1, the supports 42 are formed in a one-to-one correspondence with the connection terminals 60 and may thus be flexibly deformed depending on the stress applied to the individual connection terminals 60.

### Example 2

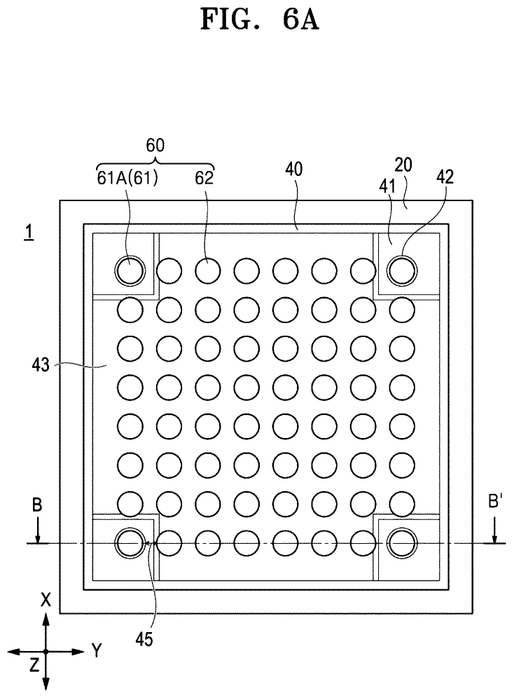

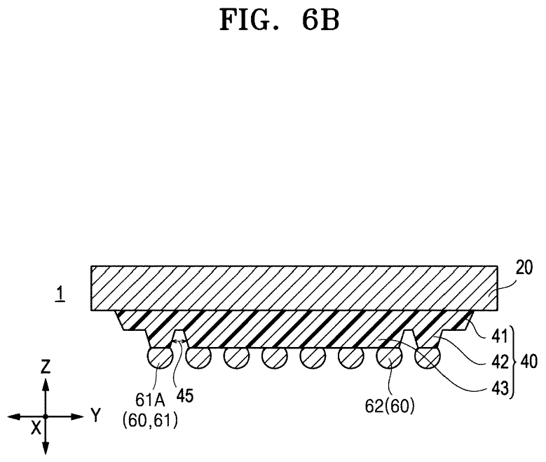

FIG. 6A is a plan view of the semiconductor device 1 having the resin layer 40 in Example 2. FIG. 6B is a schematic cross-sectional view of the semiconductor device 1 taken along line B-B′ of FIG. 6A.

As shown in FIGS. 6A and 6B, in Example 2, the support 42 may be located corresponding to the connection terminal 60 that is located at the position farthest from the center of the semiconductor chip 20 in a plan view. For example, the plurality of connection terminals 60 may include the first connection terminals 61. The plurality of connection terminals 60 may further include the second connection terminals 62. The first connection terminals 61 may include an outermost connection terminal 61A, and the outermost connection terminal 61A may be disposed at the position farthest from the center of the semiconductor chip 20. The supports 42 may be located between outermost connection terminals 61A and the semiconductor chip 20. As shown in FIG. 6A, a plurality of outermost connection terminals 61A may be provided. In this case, the plurality of outermost connection terminals 61A may be provided at the corners of the resin layer 40 in a plan view. The corners of the resin layer 40 may respectively correspond to the corners of the semiconductor device 1. For example, the corners of the semiconductor device 1 may include the corners of the resin layer 40. The number of corners of the resin layer 40 may be four. The number of corners of the semiconductor device 1 may be four. Stress may easily occur at the four corners of the semiconductor device 1, which are susceptible to high stress. According to Example 2, the supports 42 may be provided corresponding to the outermost connection terminals 61A at the four corners of the resin layer 40, thereby effectively relieving stress. The stress may occur due to deformation caused by heat shrinkage, etc.

### Example 3

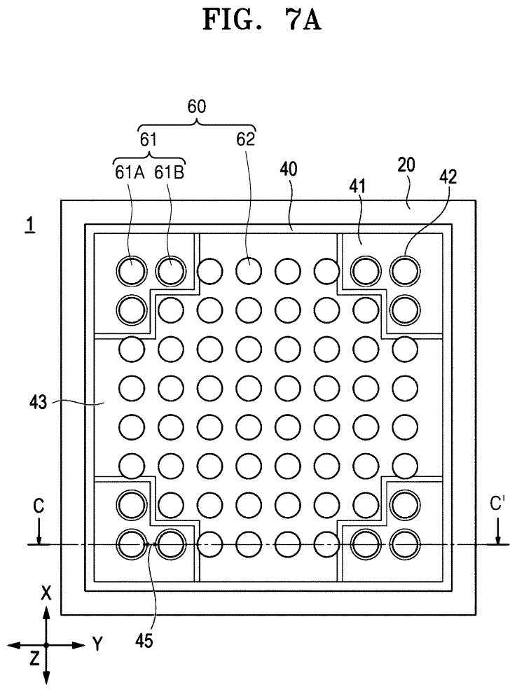

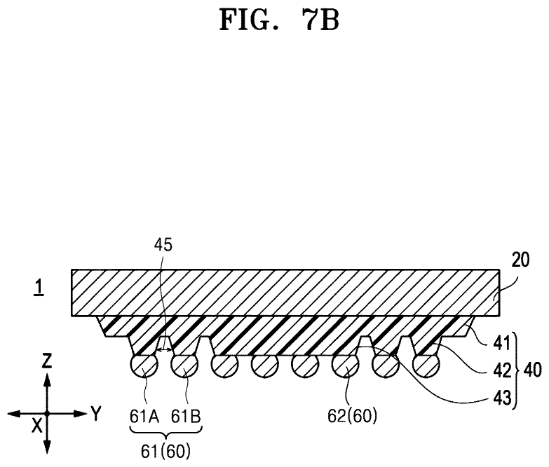

FIG. 7A is a plan view of the semiconductor device 1 having the resin layer 40 in Example 3. FIG. 7B is a schematic cross-sectional view of the semiconductor device 1 taken along line C-C′ of FIG. 7A.

As shown in FIGS. 7A and 7B, according to Example 3, the connection terminals 60 may include the first connection terminals 61. The first connection terminals 61 may include the outermost connection terminal 61A and an adjacent connection terminal 61B. The outermost connection terminal 61A may be located at the position farthest from the center of the semiconductor chip 20 in a plan view. The adjacent connection terminal 61B may be located adjacent to the outermost connection terminal 61A. For example, no other connection terminal 60 may be provided between the outermost connection terminal 61A and the adjacent connection terminal 61B. One (e.g., a first support) of the supports 42 may be formed corresponding to the outermost connection terminal 61A. For example, the one support 42 (e.g., the first support) may be located between the outermost connection terminal 61A and the semiconductor chip 20. Another (e.g., a second support) of the supports 42 may be formed corresponding to the adjacent connection terminal 61B. The another support 42 (e.g., the second support) may be located between the adjacent connection terminal 61B and the semiconductor chip 20. As shown in FIG. 7A, the plurality of outermost connection terminals 61A may be arranged at the corners of the resin layer 40 in a plan view. One of a plurality of adjacent connection terminals 61B may be adjacent to one of the outermost connection terminals 61A and spaced apart from the outermost connection terminals 61A in the X-axis direction. One other of the plurality of adjacent connection terminals 61B may be adjacent to the outermost connection terminal 61A and spaced apart from the outermost connection terminal 61A in the Y-axis direction. Three connection terminals 60 may be arranged at one corner of the resin layer 40. The supports 42 may be arranged respectively to correspond to the three adjacent connection terminals 60. The three adjacent connection terminals 60 may include one outermost connection terminal 61A and two adjacent connection terminals 61B corresponding thereto. As shown in FIG. 7A, in the semiconductor device 1, extremely high stress may be easily applied to the four corners of the semiconductor device 1. According to Example 3, the supports 42 may be arranged corresponding to the outermost connection terminals 61A and the adjacent connection terminals 61B, thereby effectively relieving stress. The stress may occur due to deformation caused by heat shrinkage, etc.

### Example 4

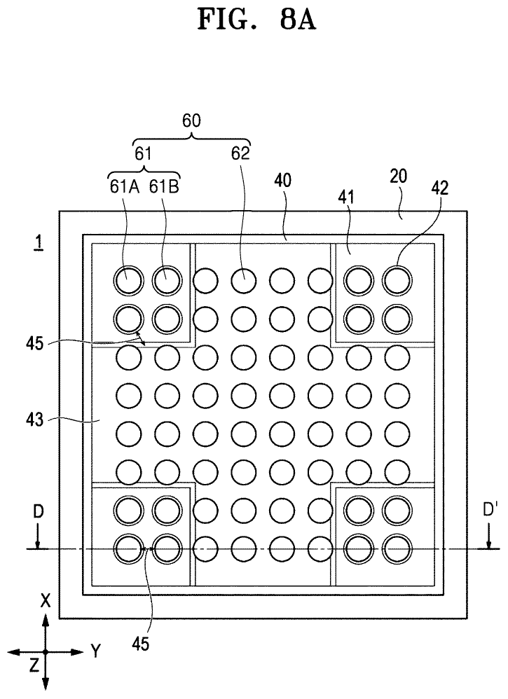

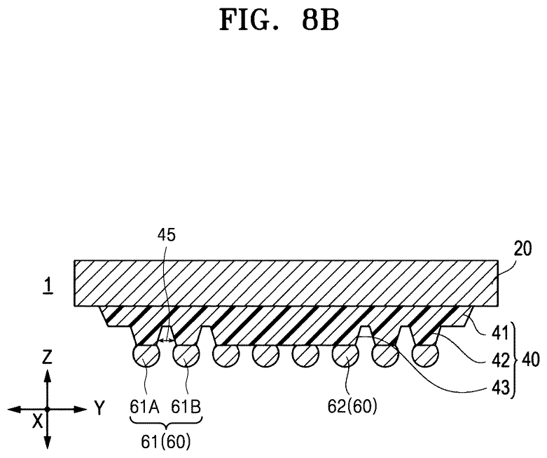

FIG. 8A is a plan view of the semiconductor device 1 having the resin layer 40 in Example 4. FIG. 8B is a schematic cross-sectional view of the semiconductor device 1 taken along line D-D′ of FIG. 8A.

As shown in FIGS. 8A and 8B, according to Example 4, the connection terminals 60 may include the first connection terminals 61. The first connection terminals 61 may include the outermost connection terminals 61A and the adjacent connection terminals 61B. Each of the outermost connection terminals 61A may be located at the position farthest from the center of the semiconductor chip 20 in a plan view. The adjacent connection terminals 61B may be located adjacent to the outermost connection terminals 61A. The planar arrangement of the adjacent connection terminals 61B may be similar to that described in the example shown in FIGS. 7A and 7B. However, one other of the adjacent connection terminals 61B may be adjacent to the corresponding outermost connection terminal 61A and spaced apart from the corresponding outermost connection terminal 61A in a diagonal direction in a plan view. The diagonal direction may be parallel to the second surface 20b of the semiconductor chip 20 and intersect the X-axis direction and the Y-axis direction. One (e.g., the first support) of the supports 42 may be formed corresponding to the outermost connection terminal 61A, and one other (e.g., the second support) of the supports 42 may be formed corresponding to the adjacent connection terminal 61B. For example, one (e.g., the first support) of the supports 42 may be located between the outermost connection terminal 61A and the semiconductor chip 20, and one other (e.g., the second support) of the supports 42 may be located between the adjacent connection terminal 61B and the semiconductor chip 20. Accordingly, in a plan view, the supports 42 may be provided respectively corresponding to the four connection terminals 60 adjacent to any one of the corners of the resin layer 40. The four adjacent connection terminals 60 may include one outermost connection terminal 61A and three adjacent connection terminals 61B corresponding thereto.

Extremely high stress may be easily applied to the four corners of the semiconductor device 1. According to Example 4, the supports 42 may be provided respectively corresponding to the four connection terminals 60 arranged near each of the four corners of the resin layer 40, thereby effectively relieving stress. The stress may occur due to deformation caused by heat shrinkage, etc.

### Example 5

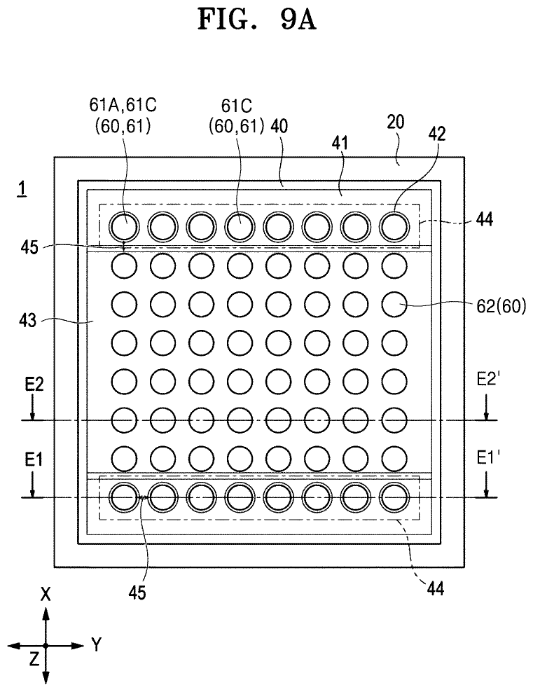

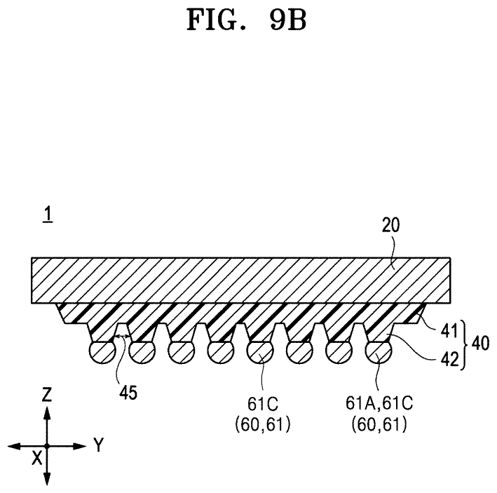

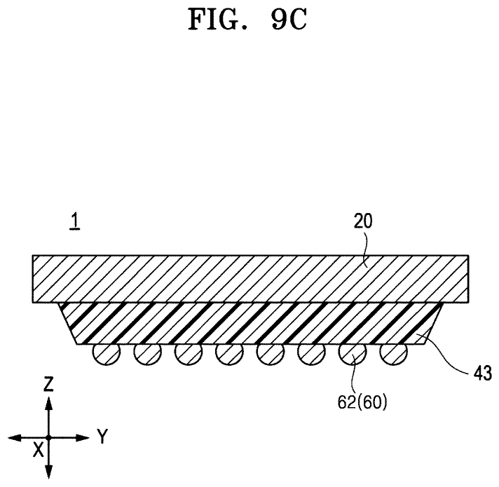

FIG. 9A is a plan view of the semiconductor device 1 having the resin layer 40 in Example 5. FIG. 9B is a schematic cross-sectional view of the semiconductor device 1 taken along line E1-E1′ of FIG. 9A. FIG. 9C is a schematic cross-sectional view of the semiconductor device 1 taken along line E2-E2′ of FIG. 9A.

As shown in FIGS. 9A, 9B, and 9C, according to Example 5, the connection terminals 60 may be located at the positions farthest from the center of the semiconductor chip 20 in a plan view, and the supports 42 respectively corresponding to the connection terminals 60 and arranged in the same straight line as the connection terminals 60 may be provided in an outer peripheral region 44 of the resin layer 40. For example, the connection terminals 60 may be arranged in rows and columns in a plan view. The rows may be parallel to the X-axis direction, and the columns may be parallel to the Y-axis direction. The connection terminals 60 may include the first connection terminals 61. The first connection terminals 61 may include outer connection terminals 61C. The outer connection terminals 61C may form the outermost row. The outer connection terminals 61C may include the outermost connection terminals 61A described above. The outer connection terminals 61C may be provided on the outer peripheral region 44 of the resin layer 40. The supports 42 may be respectively arranged between the outer connection terminals 61C and the semiconductor chip 20. Two outermost rows of the connection terminals 60 may be provided. For example, the outermost rows of the connection terminals 60 may include first and last rows. Accordingly, a plurality of outer peripheral regions 44 of the resin layer 40 may be provided. The outer peripheral regions 44 of the resin layer 40 may extend in the X-axis direction in a plan view.

As shown in FIGS. 9A and 9C, the resin layer 40 may further include the ridge 43. The ridge 43 may be laterally spaced apart from the support 42. The connection terminals 60 (e.g., the second connection terminals 62) other than the outer connection terminals 61C may be arranged on the ridge 43. Extremely high stress may be easily applied to the four corners of the semiconductor device 1. According to Example 5, the supports 42 may be provided corresponding to the outer connection terminals 61C, thereby effectively relieving stress. The stress may occur due to deformation caused by heat shrinkage, etc.

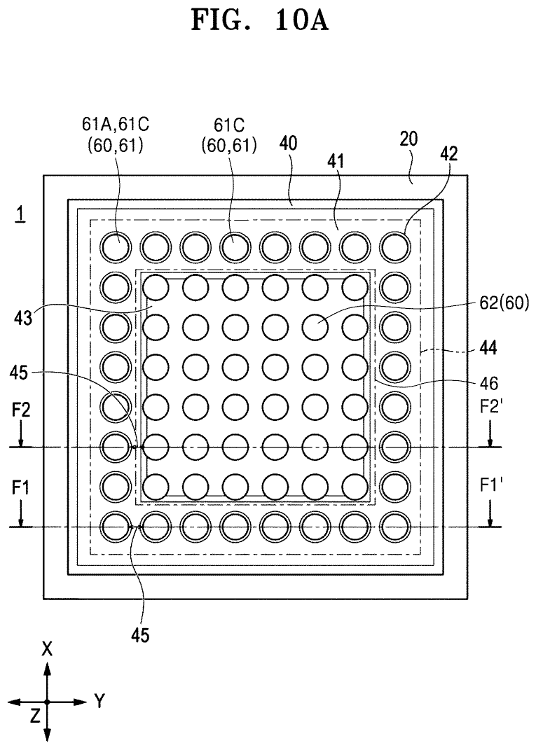

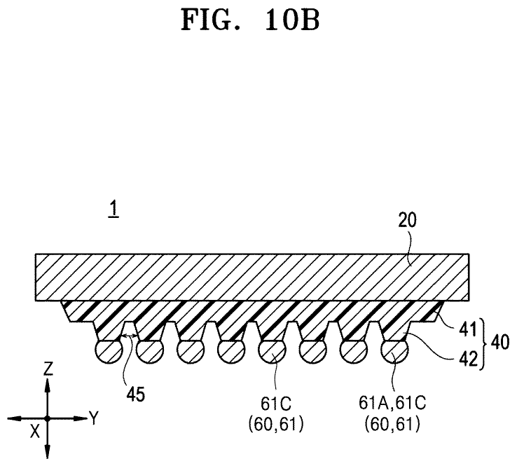

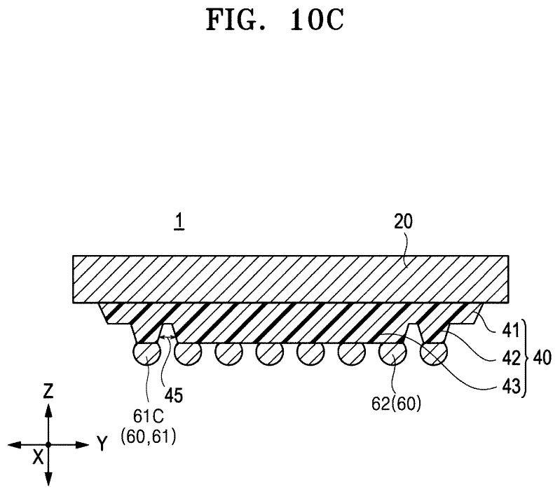

FIG. 10A is a plan view of the semiconductor device 1 having the resin layer 40 in Example 6. FIG. 10B is a schematic cross-sectional view of the semiconductor device 1 taken along line F1-F1′ of FIG. 10A. FIG. 10C is a schematic cross-sectional view of the semiconductor device 1 taken along line F2-F2′ of FIG. 10A.

As shown in FIGS. 10A, 10B, and 10C, according to Example 6, the connection terminals 60 may be located at the positions farthest from the center of the semiconductor chip 20 in a plan view, and the supports 42 may be formed respectively corresponding to the connection terminals 60 arranged in the outer peripheral region 44 of the resin layer 40 including the connection terminals 60. The supports 42 are formed respectively corresponding to the connection terminals 60 arranged at the four corners of the resin layer 40, as shown in FIGS. 10A and 10B. In addition, as shown in FIG. 10A, the supports 42 are formed individually not only at the four corners of the resin layer 40 but also at the connection terminals 60 arranged in other regions of the outer peripheral region 44 of the resin layer 40. As shown in FIGS. 10A and 10C, the connection terminals 60 (e.g., the second connection terminals 62) other than the connection terminals 60 (e.g., the first connection terminals 61) arranged on the supports 42 are formed on the ridge 43.

Also, in Example 5 and Example 6, the “outer peripheral region 44” is defined as a region of the boundary shape expressed by a dash-single dotted line in FIGS. 9A and 10A, and represents an outer peripheral portion of the resin layer 40 in a region of the resin layer 40 in which the connection terminals 60 are formed. The outer peripheral region 44 may include a region of the resin layer 40 in which the connection terminals 60 are formed at least on the outermost peripheral side, among regions of the resin layer 40 in which the connection terminals 60 are formed. In this example, the outer peripheral region 44 may be indicated by the region surrounded by the dash-single dotted line in FIG. 9A, etc.

In the semiconductor device 1, the connection terminals 60 farthest from the center of the semiconductor chip 20 in a plan view are most susceptible to stress. Therefore, as shown in Examples 1 to 6 described above, the supports 42 may be arranged respectively corresponding to the connection terminals 60 that are farthest from the center of the semiconductor chip 20 in a plan view.

Also, the thicknesses of the plurality of supports 42 relative to the thickness of the resin layer 40 may be substantially uniform. Alternatively, the thicknesses of the supports 42 relative to the thickness of the resin layer 40 may be different from each other. The thicknesses of the supports 42 may vary depending on the specifications of the package structure of the semiconductor device 1 and may be set appropriately according to the stress applied to the connection terminals 60. For example, the semiconductor chip 20 may include a center region 46 and an outer peripheral region 44 surrounding the center region 46 in a plan view. Also, examining the thicknesses of the supports 42 relative to the thickness of the resin layer 40, the thickness of the support 42 located in the center region (the central side) of the semiconductor chip 20 in a plan view may be greater than the thickness of the support 42 located in the outer peripheral region (the outer peripheral side) of the semiconductor chip 20. Accordingly, the reliability of solder connection may be improved.

The semiconductor device 1 may include dummy terminals that are not electrically connected, instead of the outermost connection terminals 61A. When the semiconductor device 1 includes the dummy terminals, the support 42 may be formed corresponding to the connection terminal 60 farthest from the center of the semiconductor chip 20, except for the dummy terminals.

Referring back to FIGS. 1 and 2, each of the connection terminals 60 arranged on the resin layer 40 may be connected to electrodes 22 of the semiconductor chip 20 via a plurality of wires 50. Each of the wiring layers 50 may include a metal material and may be provided as a single layer or a plurality of stacked layers. The metal material may include copper (Cu), aluminum (Al), and/or gold (Au). The wire 50 may be formed by a photolithography method or the like. The wire 50 may be formed on the terminal surface 42a of the corresponding support 42 or the terminal surface 43a of the ridge 43, between the connection terminal 60 and the resin layer 40.

Next, an example layout of the wire 50 is illustrated. The wire 50 may be provided as shown below in layout examples 1 to 3. Also, the wire 50 is not limited to the examples shown in layout examples 1 to 3 and may be provided by methods other than those described in layout examples 1 to 3. Hereinafter, the support 42 is described below for simplicity of description.

### Layout Example 1

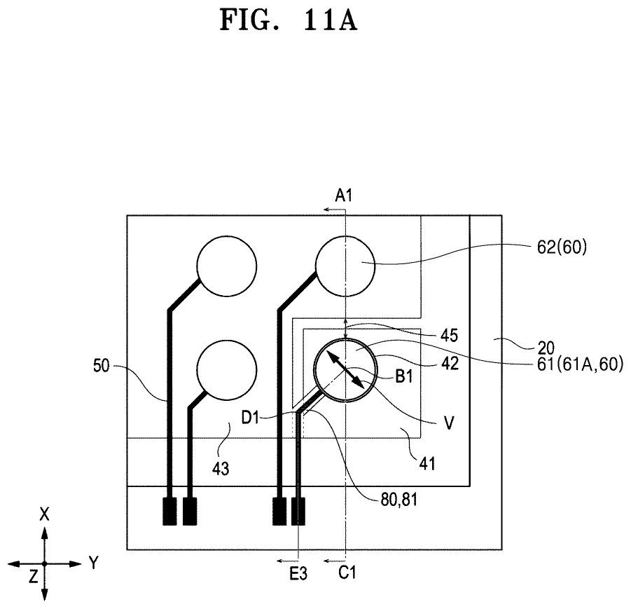

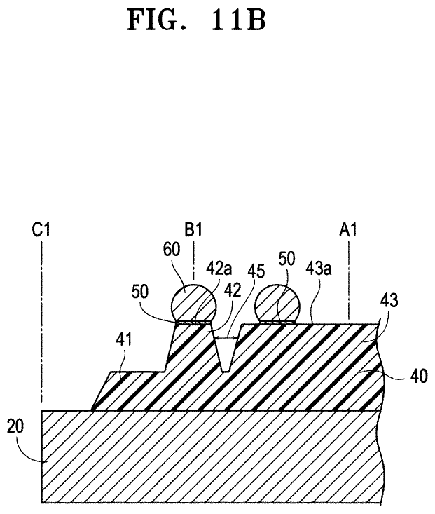

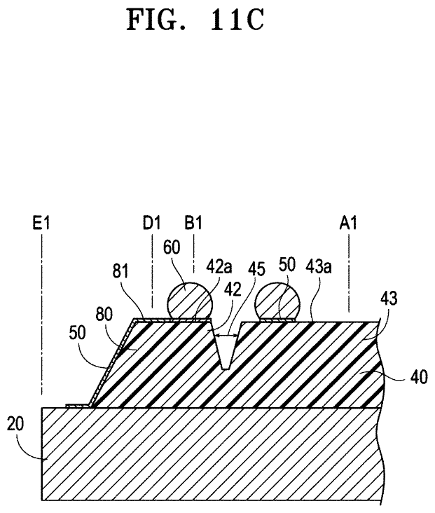

FIG. 11A is a plan view schematically showing the wire 50 in the semiconductor device 1 in layout example 1. FIG. 11B is a schematic cross-sectional view of the semiconductor device 1 taken along line A1-B1-D1-E3 of FIG. 11A. FIG. 11C is a schematic cross-sectional view of the semiconductor device 1 taken along line A1-B1-C1 of FIG. 11A. Hereinafter, the support 42 and the ridge 43, each of which is provided in a singular form, are described.

The wire 50 may be provided as shown in layout example 1 in FIGS. 11A, 11B, and 11C. According to layout example 1, as shown in FIG. 11A, a bridge 80 is provided in the gap 45 between the support 42 and the ridge 43. The gap 45 may have a groove shape. The connection terminals 60 are disposed on each of the support 42 and the ridge 43 as shown in FIGS. 11A and 11B.

As shown in FIGS. 11A and 11C, the bridge 80 has a wiring surface 81. The wiring surface 81 of the bridge 80 may be connected to the terminal surface 42a of the corresponding support 42 and the terminal surface 43a of the ridge 43. The wiring surface 81 of the bridge 80 may include a wiring formation surface. For example, the wire 50 may be formed on the wiring surface 81 of the bridge 80. For example, as shown in FIG. 11C, the height position of the wiring surface 81 may be substantially the same as the height position of the terminal surface 42a of the support 42 and the height position of the terminal surface 43a of the ridge 43 in the thickness direction (the Z-axis direction) of the resin layer 40. Therefore, the wiring surface 81 of the bridge 80 may be provided on a surface that is substantially the same as the terminal surface 42a of the support 42 and the terminal surface 43a of the ridge 43.

The support 42 on which the wire 50 is provided, may be subject to principal stress in a particular direction. The direction of principal stress refers to an orientation within the support 42 where a normal stress reaches a maximum or minimum, and shear stress is zero. The principal stress arises internally as a result of mechanical loading, thermal expansion mismatch, structural deformation, or other stress-inducing conditions. The bridge 80 may be arranged so as to extend in a direction intersecting a direction V of the principal stress (a thick arrow direction in FIG. 11A), preferably in a direction perpendicular to the direction V. Accordingly, the bridge 80 does not hinder deformation of the support 42 when stress is applied to the support 42. Therefore, the support 42 may be deformed in response to stress. Also, the bridge 80 does not need to entirely extend in a direction intersecting the direction V of the principal stress applied to the support 42. For example, the effect described above may be achieved when at least a portion of the bridge 80 extends in a direction intersecting the direction V of the principal stress. At least the portion of the bridge 80 may be relatively close to the support 42. Specifically, at least the portion of the bridge 80 may include a connecting portion with the support 42 and a portion of a certain region including the connecting portion.

According to layout example 1, the wire 50 may be provided so as to pass through the terminal surface 43a of the ridge 43 and the wiring surface 81 of the bridge 80 and so as to be connected to the connection terminal 60 (e.g., the first connection terminal) disposed on the support 42. The wire 50 is provided in a direction in which the bridge 80 extends. The wire 50 provided according to layout example 1 prevents wire breakage because the bridge 80 may deform in response to stress deformation of the support 42.

### Layout Example 2

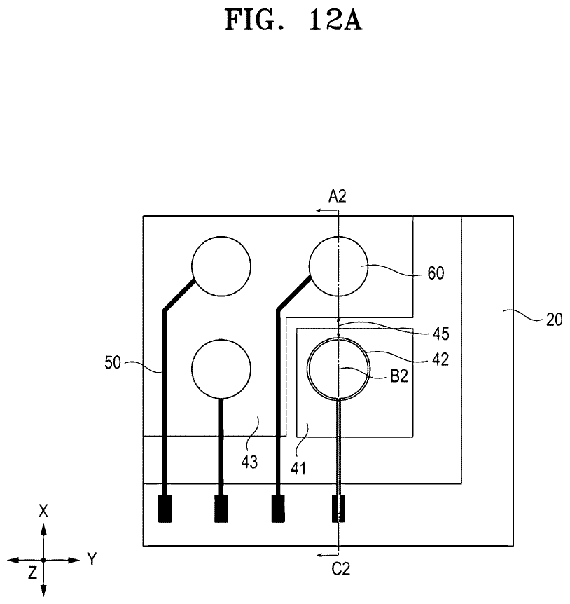

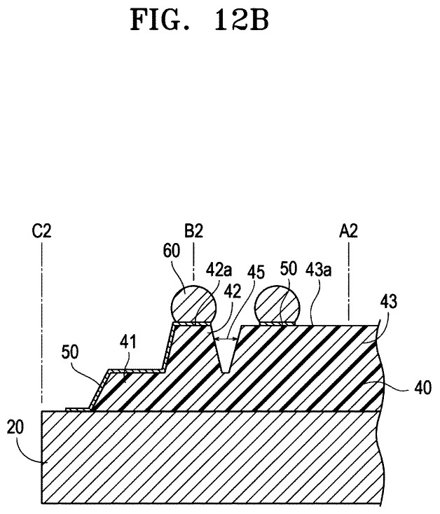

FIG. 12A is a plan view schematically showing the wire 50 in the semiconductor device 1 in layout example 2. FIG. 12B is a schematic cross-sectional view of the semiconductor device 1 taken along line A2-B2-C2 of FIG. 12A.

The wire 50 may be provided in layout example 2 illustrated in FIGS. 12A and 12B. According to layout example 2, the wire 50 may be provided so as to be connected to the connection terminal 60 along concave-convex portions of the outer surface of the support 42. According to layout example 2, the bridge 80 of layout example 1 may not be used. The wire 50 may be provided along the outer surface of other components of the resin layer 40 in addition to the outer surface of the support 42. The other components of the resin layer 40 may include, for example, the base 41 and the ridge 43.

### Layout Example 3

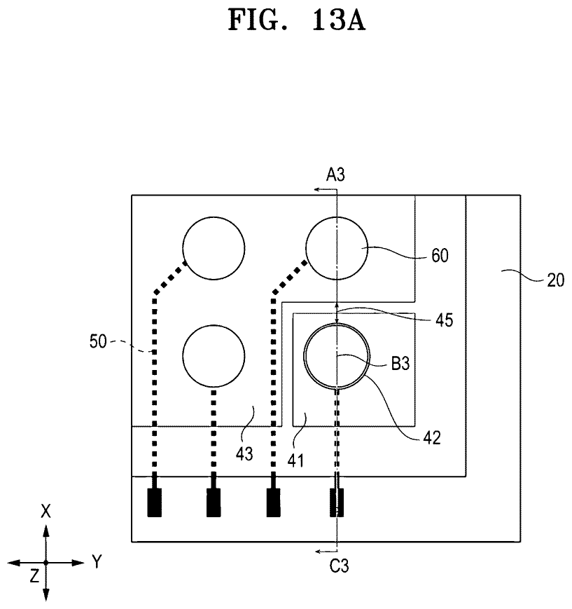

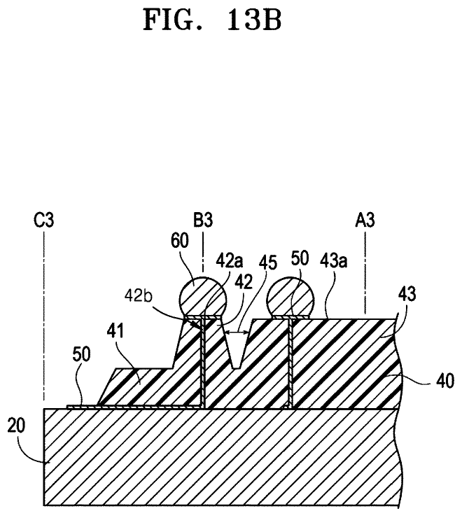

FIG. 13A is a plan view schematically showing the wire 50 in the semiconductor device 1 in layout example 3. FIG. 13B is a schematic cross-sectional view of the semiconductor device 1 taken along line A3-B3-C3 of FIG. 13A.

The wire 50 may be provided in layout example 3 illustrated in FIGS. 13A and 13B. According to layout example 3, the wire 50 is provided so as to pass through the inside of the support 42 and be connected to the connection terminal 60. In layout example 3, the wire 50 may be electrically connected to the connection terminal 60 through a through-via 42b formed in the support 42. The wire 50 patterned before formation of the support 42 may be formed in the insulating layer 30. After the support 42 is formed, the through-via 42b may be formed from the terminal surface 42a toward the patterned wire 50. The wire 50 is electrically connected to the connection terminal 60 via a through-electrode or a pillar-shaped electrode. The through-electrode may be formed on the through-via 42b by a method such as plating. The pillar-shaped electrode may include a copper pin inserted into the through-via 42b.

Referring back to FIGS. 1 and 2, the plurality of connection terminals 60 are formed in the resin layer 40.

The connection terminals 60 include a conductive material, such as solder. The connection terminals 60 are disposed on the terminal surface 42a of the support 42 of the resin layer 40 or on the terminal surface 43a of the ridge 43 and are electrically connected to the wire 50. The shape and size of the connection terminal 60 may be determined appropriately according to the specifications of the semiconductor device 1. The connection terminal 60 may include a terminal for electrically connecting the semiconductor device 1 to the substrate 200. The connection terminal 60 may function as a structural connecting member. A plurality of connection terminals 60 may be provided, and at least some of the plurality of connection terminals 60 may include dummy terminals that are not electrically connected.

The protective layer 70 covers exposed portions of the insulating layer 30 and the wire 50. The protective layer 70 may include an insulating material. The protective layer 70 may be formed by using the same material as the resin layer 40. The protective layer 70 may be formed in advance so as not to cover a contact region between the wire 50 and the connection terminal 60. Alternatively, the protective layer 70 may be formed by completely covering the insulating layer 30 and the wire 50, and then, the protective layer 70 may be partially removed. The removed portion of the protective layer 70 may include the contact region between the wire 50 and the connection terminal 60.

As described above, the semiconductor device 1 in some embodiments may have a package structure that may be mounted on the substrate 200. The semiconductor device 1 includes the semiconductor chip 20 having the first surface 20a and the second surface 20b opposite to the first surface 20a, the plurality of connection terminals 60 for electrically connecting the semiconductor chip 20 to the substrate 200, and the resin layer 40 having the thickness of about 100 μm to about 200 μm and provided between the second surface 20b of the semiconductor chip 20 and the plurality of connection terminals 60. The resin layer 40 includes one or more supports 42 protruding in the thickness direction of the resin layer 40. Also, one of the plurality of connection terminals 60 is disposed on the support 42, and the support 42 has the thickness that is 33% or more of the thickness of the resin layer 40.

In the semiconductor device 1 having the structure described above, the resin layer 40 includes the supports 42 on which the connection terminals 60 are individually arranged, and thus, the supports 42 are individually deformed according to the stress. Therefore, the semiconductor device 1 may effectively reduce deformation due to temperature changes and improve the reliability of solder connection when mounted on the substrate 200. The stress described above may be applied when the heat shrinkage occurs due to temperature changes in a temperature cycle.

### Embodiments

Next, embodiments are described in the present disclosure, but the present disclosure is not limited to the following embodiments.

Hereinafter, a simulation has been performed to identify the reliability of solder connection in the semiconductor device according to some embodiments. The simulation has been conducted as follows.

### Specifications, Software, and Analysis Methods

Nonlinear finite element analysis software, Marc (registered trademark), by MSC Software Corporation is used for analysis software, and the analysis is performed by using the finite element method (FEM).

### Simulation Condition

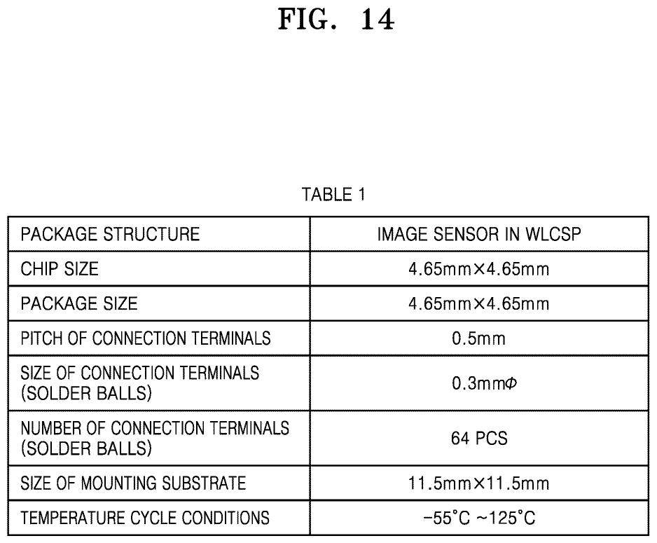

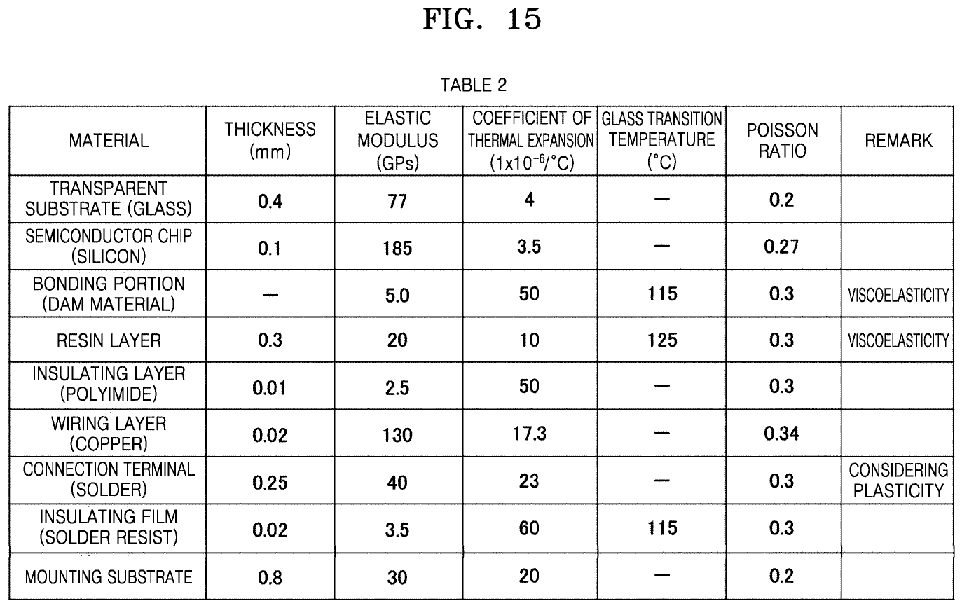

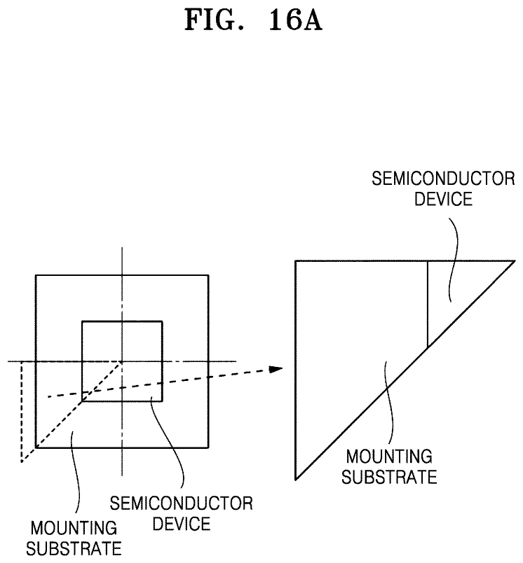

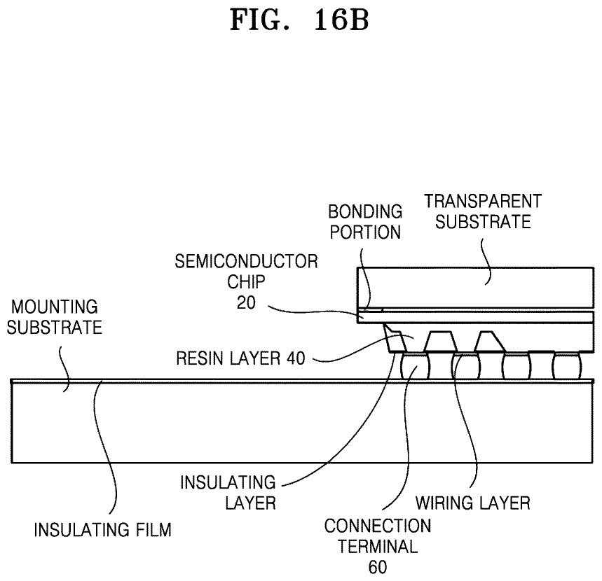

“Model conditions” and “material properties” used as the simulation conditions are shown in Table 1 of FIG. 14 and Table 2 of FIG. 15. Also, the shape of the simulation model and the configuration of each part are shown in FIGS. 16A and 16B. As shown in FIGS. 16A and 16B, the simulation model of each sample is made by cutting a package mounted on a mounting substrate into ⅛ size in a plan view. The number of simulated samples is 30. The package structure of the semiconductor device shown in Table 1 may include an image sensor in a wafer-level chip scale package (WLCSP) of the semiconductor chip 20. The insulating layer in FIG. 16B may correspond to the protective layer 70 in FIG. 1, but the embodiment is not limited thereto.

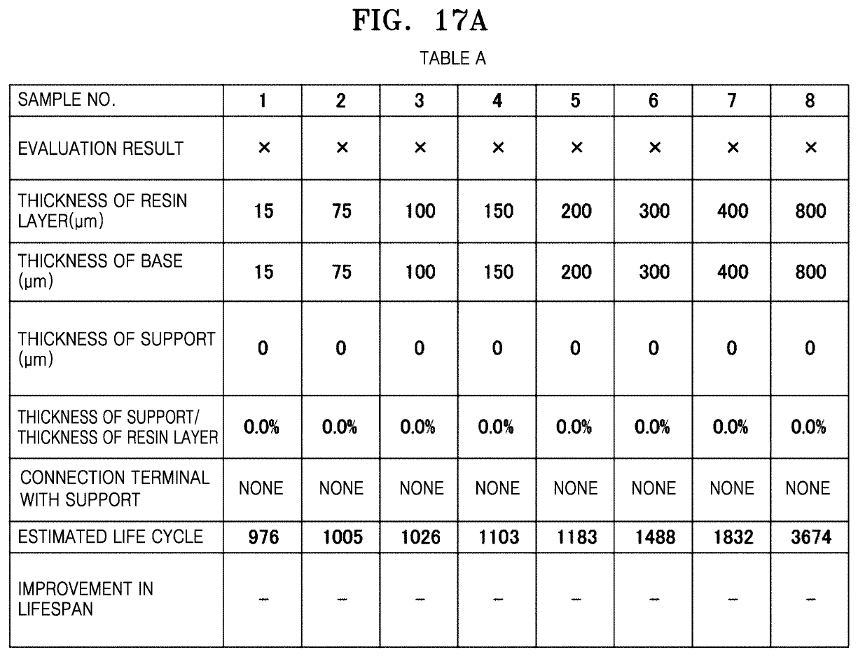

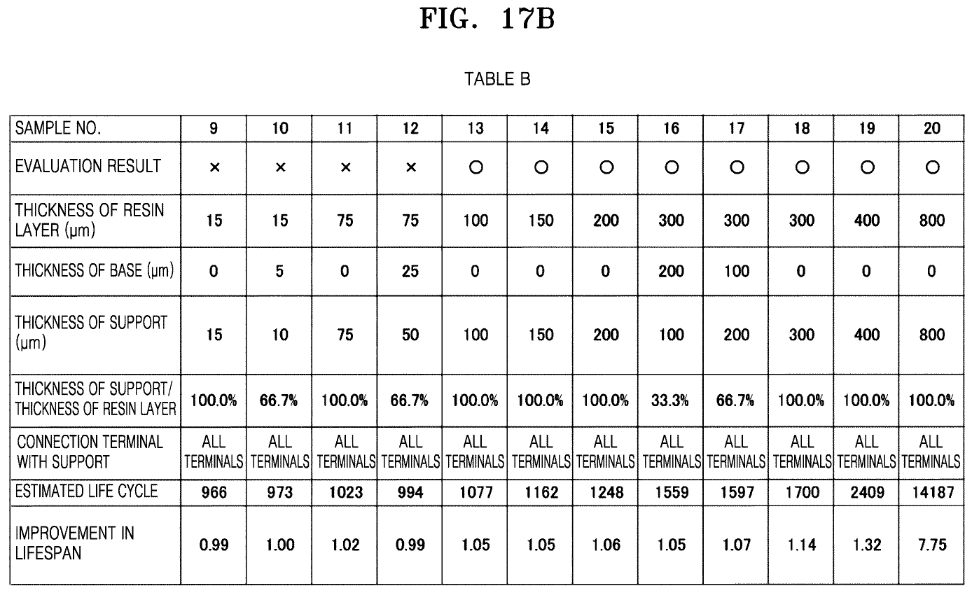

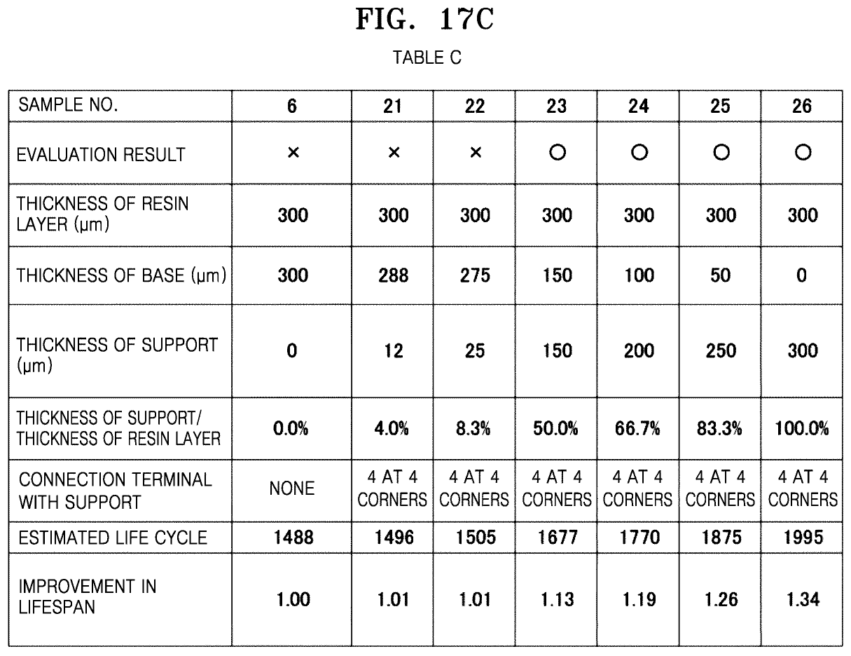

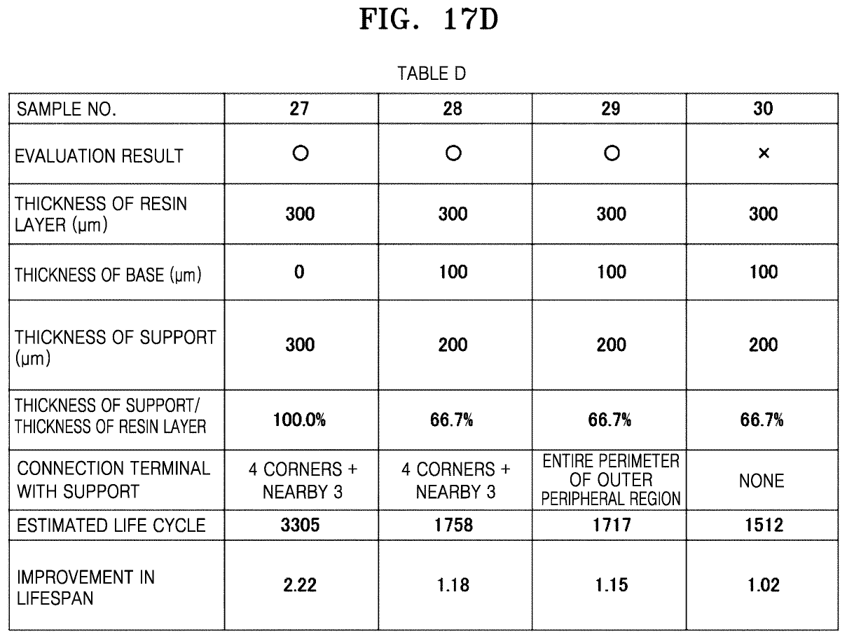

FIGS. 17A to 17D show simulation results according to the embodiment. Samples 9 to 30 show the improvement in lifespan calculated when a sample having the same thickness of the resin layer is selected as a reference from among samples 1 to 8 shown in Table A of FIG. 17A. The evaluation of the characteristics of samples 9 to 30 shown in Tables B to D of FIGS. 17B to 17D is performed by assigning “O” to samples having the solder lifespan greater than or equal to 1.0455 times that of the reference and by assigning “X” to samples having the solder lifespan less than 1.0455 times that of the reference. The evaluation criteria are based on the fact that, when the number of life cycles of the sample is less than 1.0455 times the number of life cycles of the reference, the number of life cycles of the sample falls within the 2σ range of the standard deviation of the number of life cycles of the reference, and thus, it may be determined that the number of life cycles of the sample falls within a range of inconsistency of the number of life cycles of the reference.

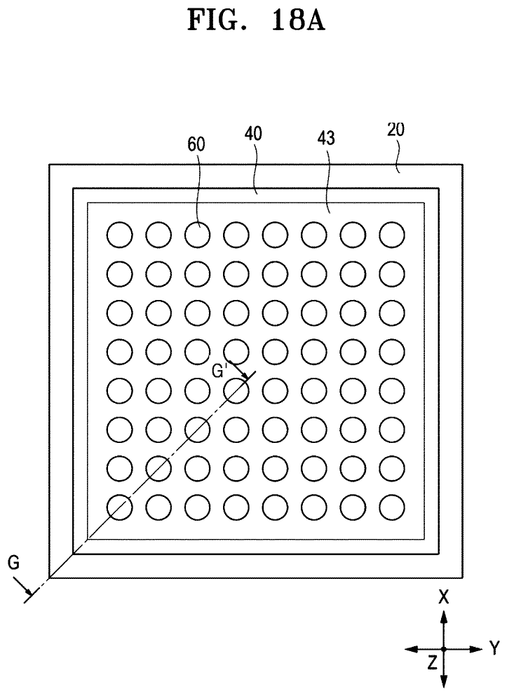

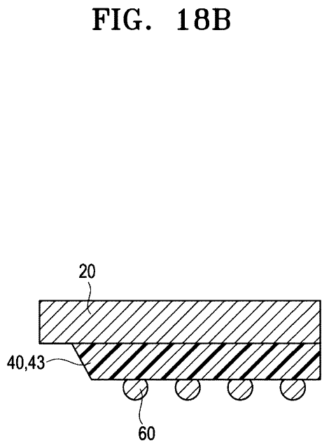

The structure of each sample is as follows. FIGS. 18A, 19A, 20A, 21A, 22A, and 23A are plan views entirely showing package structures before samples are cut into ⅛ size. FIGS. 18B, 19B, 20B, 21B, 22B, and 23B are schematic cross-sectional views of the corresponding package structures.

As shown in FIGS. 18A and 18B, in samples 1 to 8, the shape of the resin layer 40, on which the plurality of connection terminals 60 are arranged, represents the ridge 43. That is, samples 1 to 8 show some embodiments in which all of the connection terminals 60 are arranged on one ridge 43. Also, samples 1 to 8 are used as references for the sample having the same thickness of the resin layer 40 among samples 9 to 30.

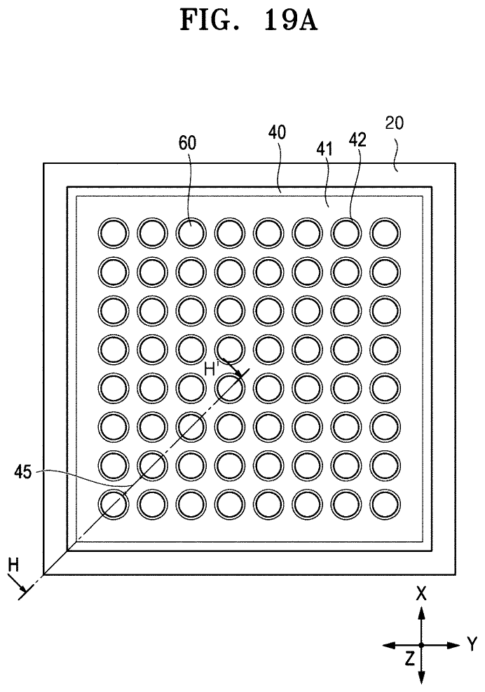

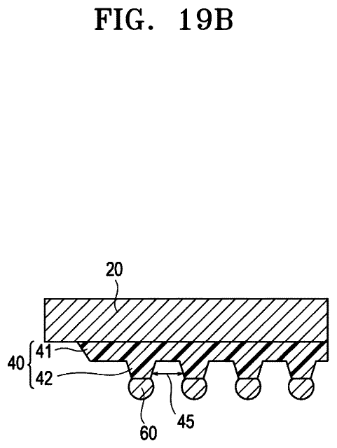

As shown in FIGS. 19A and 19B, the resin layer 40 of samples 9 to 20 has a structure corresponding to Example 1 described above (see FIGS. 4A and 4B). That is, according to samples 9 to 20, all of the connection terminals 60 are respectively disposed on the plurality of supports 42.

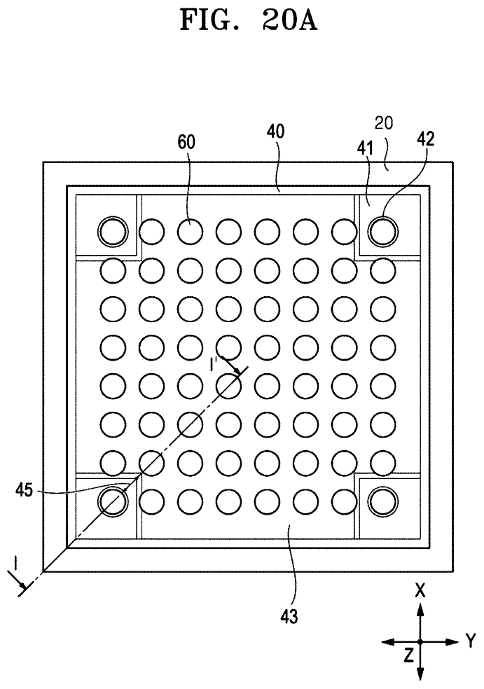

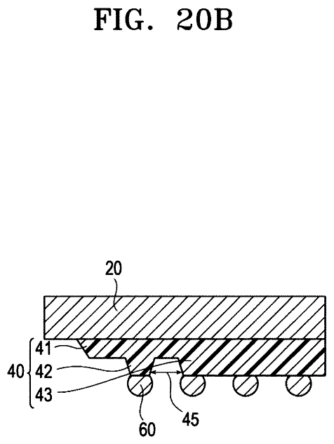

As shown in FIGS. 20A and 20B, the resin layer 40 of samples 21 to 26 has a structure corresponding to Example 2 described above (see FIGS. 5A and 5B). That is, according to samples 21 to 26, the connection terminals 60, which are located at the four corners of the resin layer 40 farthest from the center of the semiconductor chip 20 in a plan view, are respectively disposed on the supports 42.

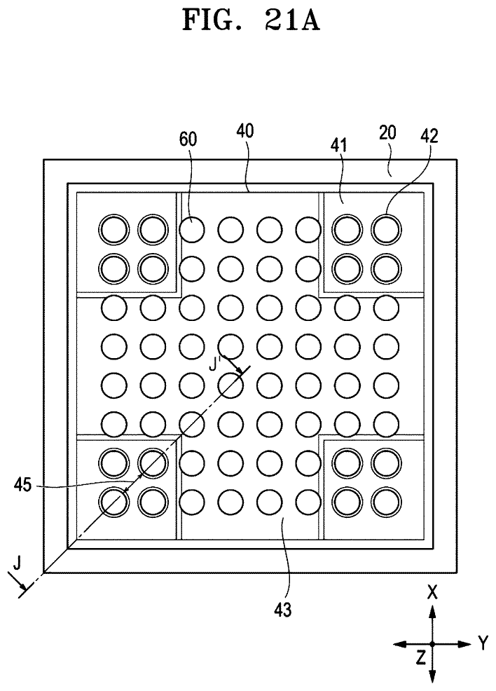

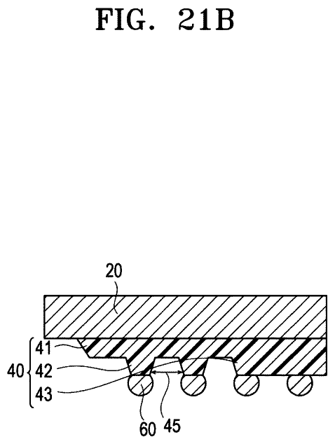

As shown in FIGS. 21A and 21B, the resin layer 40 of samples 27 and 28 has a structure corresponding to Example 4 described above (see FIGS. 8A and 8B). That is, according to samples 27 and 28, the connection terminals 60 at the four corners, which are located at the positions farthest from the center of the semiconductor chip 20 in a plan view, and the three connection terminals 60, which are adjacent to the connection terminal 60 at the four corners, are individually disposed on the supports 42.

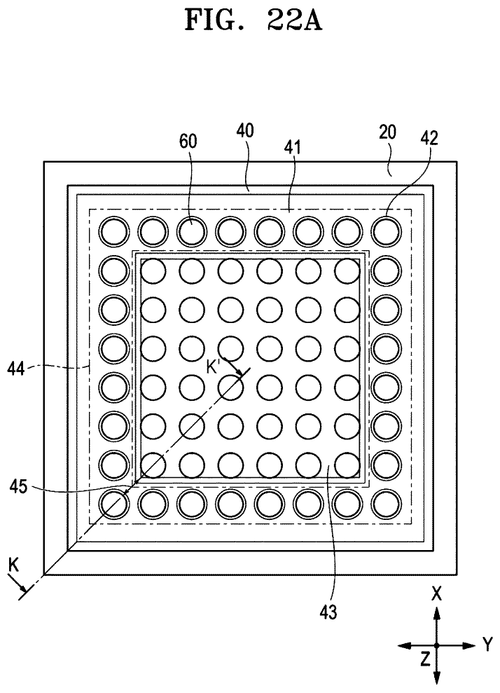

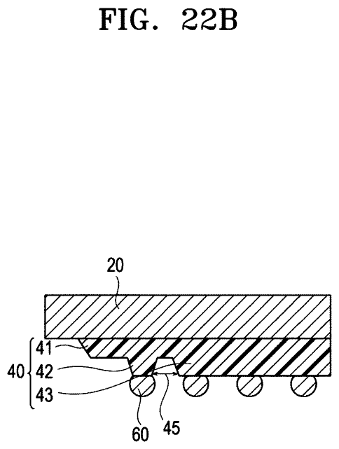

As shown in FIGS. 22A and 22B, the resin layer 40 of sample 29 has a structure in which the connection terminals 60 arranged around the entire perimeter of the outer peripheral region 44 of the resin layer 40 are respectively disposed on the supports 42.

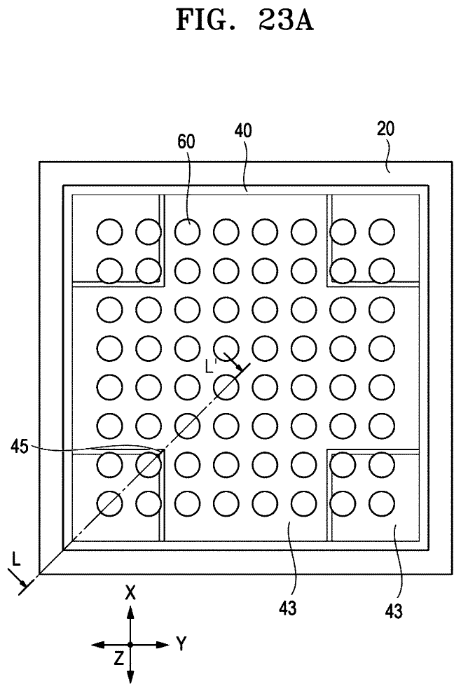

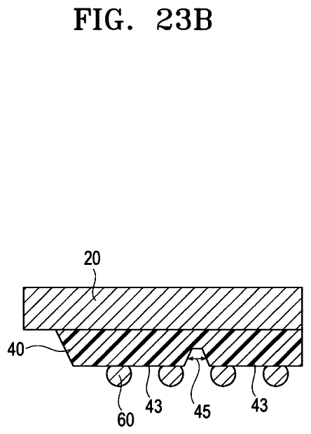

According to sample 30, as shown in FIGS. 23A and 23B, the ridge 43 is formed corresponding to the connection terminals 60 located at the positions farthest from the center of the semiconductor chip 20 in a plan view and the three connection terminals 60 adjacent to the connection terminal 60. That is, although the resin layer 40 of sample 30 is divided into the four corner portions and the other portions, the ridge 43 is formed on each of the corner regions of the resin layer 40.

The evaluation results for each sample are shown in Tables A to D in FIGS. 17A to 17D.

As shown in FIG. 17B, in samples 9 to 12 among samples 9 to 20, the thickness of the support 42 is 100 μm or less. Accordingly, the life cycles fall below the evaluation criteria, and no satisfactory results are obtained. On the other hand, in samples 13 to 20, the thickness of the support is 100 μm or more, and the thickness of the support is 33% or more of the thickness of the resin layer. Therefore, it may be identified that the life cycle exceeds the evaluation criteria, and satisfactory results are obtained.

In samples 21 and 22 among samples 21 to 26 shown in FIG. 17C, the thickness of the support is less than 33% of the thickness of the resin layer. Accordingly, the life cycle falls below the evaluation criteria, and no satisfactory results are obtained. On the other hand, in samples 23 to 26, the thickness of the support is 100 μm or more, and the thickness of the support is 33% or more of the thickness of the resin layer. Therefore, it may be identified that the life cycle exceeds the evaluation criteria, and satisfactory results are obtained.

In sample 30 among samples 27 to 30 shown in FIG. 17D, the connection terminal located at the position farthest from the center of the semiconductor chip in a plan view and three connection terminals adjacent to the connection terminal are arranged together on the ridge. Accordingly, the life cycle of sample 30 falls below the evaluation criteria, and no satisfactory results are obtained. On the other hand, in the samples 27 to 29, the connection terminals are arranged at positions farthest from the center of the semiconductor chip in a plan view, and the supports are formed respectively corresponding to the connection terminals. Also, the thickness of the support is 100 μm or more, and the thickness of the support is 33% or more of the thickness of the resin layer. As a result, it may be identified that the life cycle of the sample 31 exceeds the evaluation criteria, and satisfactory results are obtained.

As described above, the semiconductor device according to the embodiment has the features in which “the thickness of the support is 100 μm or more, and the thickness of the support is 33% or more of the thickness of the resin layer” and “the supports are formed respectively corresponding to the connection terminals.” Therefore, when the semiconductor device is mounted on the substrate, the life cycle of solder may extend and the reliability of solder connection may improve.

While the present disclosure has been described with reference to embodiments thereof, it will be understood that various changes in form and details may be made therein without departing from the spirit and scope of the following claims.

While this disclosure contains many specific embodiment details, these should not be construed as limitations on the scope of what may be claimed, equivalents thereof, as well as claims to be described later. Certain features that are described in this disclosure in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device comprising:
a substrate;
a semiconductor chip mounted on the substrate and having a first surface and a second surface opposite to the first surface;
a plurality of connection terminals configured to electrically connect the semiconductor chip to the substrate; and
a resin layer having a thickness of at least 100μm, wherein the resin layer is between the semiconductor chip and the plurality of connection terminals,
wherein the resin layer comprises a first support protruding in a thickness direction of the resin layer, a first connection terminal of the plurality of connection terminals is on the first support, and
the first support has a thickness that is at least 33% of the thickness of the resin layer.

2. The semiconductor device of claim 1, wherein the resin layer comprises a base on the second surface of the semiconductor chip, and
the base is between the first support and the semiconductor chip.

3. The semiconductor device of claim 1, wherein the plurality of connection terminals are arranged in a plurality of rows,
the plurality of connection terminals comprise outer connection terminals,
the outer connection terminals are arranged in an outermost row in a plan view,
the resin layer comprises a plurality of supports, wherein the plurality of supports comprises the first support, and
the plurality of supports are respectively arranged between the semiconductor chip and the outer connection terminals.

4. The semiconductor device of claim 1, wherein the plurality of connection terminals comprise an outermost connection terminal,
the outermost connection terminal among the plurality of connection terminals is spaced further away from a center of the semiconductor chip in a plan view than other connection terminals of the plurality of connection terminals,
the resin layer comprises a plurality of supports, wherein the plurality of supports comprise the first support, and
the plurality of supports are arranged between the semiconductor chip and the outermost connection terminal.

5. The semiconductor device of claim 1, wherein the plurality of connection terminals comprise:
an outermost connection terminal spaced further away from a center of the semiconductor chip in a plan view than other connection terminals of the plurality of connection terminals; and
an adjacent connection terminal adjacent to the outermost connection terminal, and
wherein the resin layer comprises a plurality of supports, the plurality of supports comprises the first support,
the first support of the plurality of supports is between the semiconductor chip and the outermost connection terminal, and
a second support of the plurality of supports is between the semiconductor chip and the adjacent connection terminal.

6. The semiconductor device of claim 1, wherein the plurality of connection terminals comprise a plurality of first connection terminals,
the resin layer comprises a plurality of supports, wherein the plurality of supports comprises the first support, and
the plurality of first connection terminals are respectively disposed on the plurality of supports.

7. The semiconductor device of claim 6, wherein the resin layer comprises a base between the second surface of the semiconductor chip and the plurality of supports.

8. The semiconductor device of claim 7, wherein the resin layer comprises a ridge protruding from the base, the ridge is next to the first support,
the plurality of connection terminals comprise a plurality of second connection terminals, and
the plurality of second connection terminals are on the ridge.

9. The semiconductor device of claim 8, comprising a wire connected to a first connection terminal of the plurality of first connection terminals,
wherein the resin layer comprises a bridge between the first support and the ridge adjacent to the first support,
the bridge has a wiring surface, the wiring surface of the bridge is connected to a terminal surface of the ridge and a terminal surface of the first support, and
the wire is on the first support and extends along the terminal surface of the first support and the wiring surface of the bridge.

10. The semiconductor device of claim 9, wherein at least a portion of the bridge extends in a direction intersecting a direction of principal stress within the first support, and
in a plan view, the wire extends in a direction parallel to the direction in which at least the portion of the bridge extends.

11. The semiconductor device of claim 1, comprising a wire electrically connected to one of the plurality of connection terminals,
wherein the wire extends through an inside of the support.

12. The semiconductor device of claim 1, further comprising a wire electrically connected to one of the plurality of connection terminals,
wherein the wire extends along an outer surface of the first support.

13. The semiconductor device of claim 1, wherein the resin layer comprises a plurality of supports, wherein the plurality of supports comprise the first support,
the semiconductor chip comprises a center region and an outer peripheral region surrounding the center region in a plan view, and
a thickness of the first support, in the outer peripheral region of the semiconductor chip, among the plurality of supports, is greater than a thickness of a second support, in the center region of the semiconductor chip, among the plurality of supports.

14. The semiconductor device of claim 1, wherein the resin layer comprises a photosensitive material.

15. The semiconductor device of claim 1, wherein the plurality of connection terminals comprise solder.

16. The semiconductor device of claim 1, wherein the resin layer has an elastic modulus of about 10 GPa to about 20 GPa.

17. The semiconductor device of claim 1, wherein the substrate, the semiconductor chip, the plurality of connection terminals, and the resin layer constitute a package structure, and
the package structure comprises a chip scale package or a fan-out package.

18. The semiconductor device of claim 1, wherein the semiconductor chip comprises an image sensor.

19. A semiconductor device comprising:
a substrate;
a semiconductor chip mounted on the substrate and having a first surface and a second surface opposite to the first surface;
electrodes on the first surface of the semiconductor chip;
a plurality of connection terminals on the second surface of the semiconductor chip and configured to electrically connect the semiconductor chip to the substrate;
a resin layer between the second surface of the semiconductor chip and the plurality of connection terminals;
an insulating layer between the second surface of the semiconductor chip and the resin layer;
wires on the resin layer, wherein the plurality of connection terminals are electrically connected to the electrodes via the wires; and
a protective layer covering the insulating layer and the wires,
wherein the resin layer comprises a plurality of supports protruding in a thickness direction of the resin layer,
the plurality of connection terminals comprise first connection terminals,
the first connection terminals are respectively disposed on the plurality of supports,
the resin layer has a thickness of at least 100 μm, and
each support of the plurality of supports has a thickness that is at least 33% of the thickness of the resin layer.

20. The semiconductor device of claim 19, wherein the resin layer comprises a ridge,
the plurality of connection terminals comprise a plurality of second connection terminals, and
the plurality of second connection terminals are on the ridge.
